(19) United States
(12) Patent Application Publication
(10) Pub. No.: US 2010/0246036 A1
(43) Pub. Date: Sep. 30, 2010

(54) Preliminary Controlled Pre-Deformation Treatment for the Production of Mirrors

(76) Inventors: Paolo Lagana', Frascati (IT); Leonardo Chicarella, Tagliacozzo (IT); Maurizio Felici, Percile (IT)

Correspondence Address: ALSTON & BIRD LLP, BANK OF AMERICA PLAZA, 101 SOUTH TRYON STREET, SUITE 4000, CHARLOTTE, NC, 28280-4000, US

(21) Appl. No.: 12/670,830

(22) PCT Filed: Jul. 27, 2007
(86) PCT No.: PCT/IT2007/000537

§ 371 Date: Jun. 14, 2010

(51) Int. Cl. G02B 5/08; C23C 14/02

(52) U.S. Cl. 359/838; 427/162

(57) ABSTRACT

A method for the production of mirrors entails performing a preliminary controlled pre-deformation treatment of an optical system, consisting of the following phases: calculation of the deformation of the optical system due to a selected reflecting treatment; design of a deforming layer such as to produce on the optical system a deformation opposite to the one caused by the selected reflecting treatment; and deposition on the optical system of a deforming layer on which the selected reflecting treatment will subsequently be deposited.

### TECHNICAL FIELD

The present invention relates to a preliminary controlled pre-deformation treatment for the production of mirrors.

### BACKGROUND ART

Reflecting treatments generally involve the deposition of one or more thin-film layers on the surface of an optical system. Reflecting treatments can be of three types: entirely dielectric (consisting of an alternation of thin layers of material with high and low refraction index respectively), entirely metallic or mixed metallic-dielectric structure.

The type of materials used, the thickness of each layer and their total number depend on the required characteristics of the final reflecting treatment such as, for example, high reflection in certain spectral bands and for certain angles of incidence, high resistance to laser beams and optimal characteristics of resistance to ambient operating conditions.

The high intrinsic stress contained in each layer deposited means that, once the whole reflecting treatment has been performed, the latter manifests a high residual mechanical stress such as a to deform the optical system on which it has been deposited, causing it to lose those essential requirements of form, such as planarity, conferred in the preliminary work phase.

Methods have been devised to remedy the above problems but said methods have limitations.

One of these methods acts directly on the structure of the optical system and consists in performing, on the surface opposite the one on which the reflecting treatment will be deposited, a complex machining operation to stiffen the surface, thus enabling it to withstand the residual stress induced by the reflecting treatment without any deformation of the optical system. The disadvantage of said method is that optical systems have to be produced with reinforcements on the surface opposite the working surface, thus increasing mass, machining times and costs.

Other methods are based on alteration of the structure of the reflecting treatment so that its overall deformation is nil. In particular, said methods aim to select both the materials to be used and the total structure of the reflecting treatment, not only on the basis of the required optical characteristics but also on the basis of their residual mechanical stress which must be nil. An example of one of said methods is given in the patent U.S. Pat. No. 6,134,049. The main disadvantage of this method lies in the fact that it is not possible to freely choose the materials and structure of the reflecting treatment solely for the purpose of maximising the optical characteristics and resistance. In fact, in order to ensure nil residual stress, the limitation in the choice of materials and structure can result in reflecting treatments with characteristics inferior to those that can be obtained without the above constraints.

### DISCLOSURE OF INVENTION

The aim of the present invention is to provide a method to compensate for the deformation induced by a reflecting treatment without altering the reflecting treatment itself which, therefore, can be designed without constraints, choosing the most appropriate materials and structure, and aiming to maximise performance.

The subject of the present invention is a method for the production of mirrors comprising a reflecting treatment in which one or more layers of selected material are deposited on the surface of an optical system; said method being characterised in that it comprises a preliminary controlled pre-deformation treatment of said optical system comprising the phases of:

calculation of the deformation of the optical system due to the selected reflecting treatment;

design of a deforming layer such as to produce on said optical system a deformation opposite to the one caused by said selected reflecting treatment; and

deposition on said optical system of said deforming layer, on which said selected reflecting treatment will be subsequently deposited.

### BRIEF DESCRIPTION OF THE DRAWINGS

The following non-limiting example is provided for illustrative purposes, for a better understanding of the invention with the help of the figures of the accompanying drawing, in which:

FIG. 1 illustrates the stages of the method for production of mirrors according to the present invention; and

FIG. 2 shows the interferometric measurements of the optical surface in the various phases of the method according to the present invention.

### BEST MODE FOR CARRYING OUT THE INVENTION

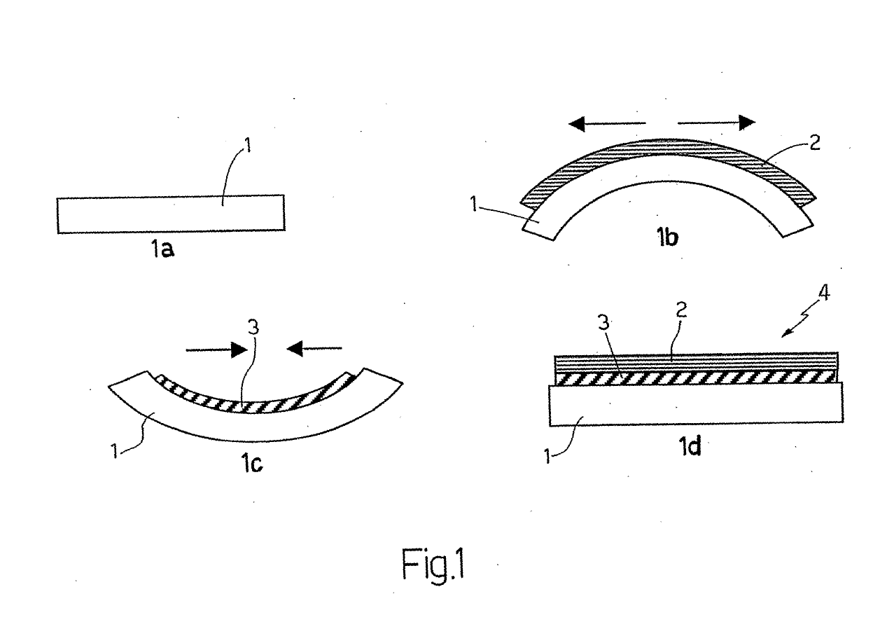

An experimental example of the production of mirrors by means of the method subject of the present invention is given below. The parts that make up the mirror produced are indicated numerically, referring to the simplified illustration of FIG. 1.

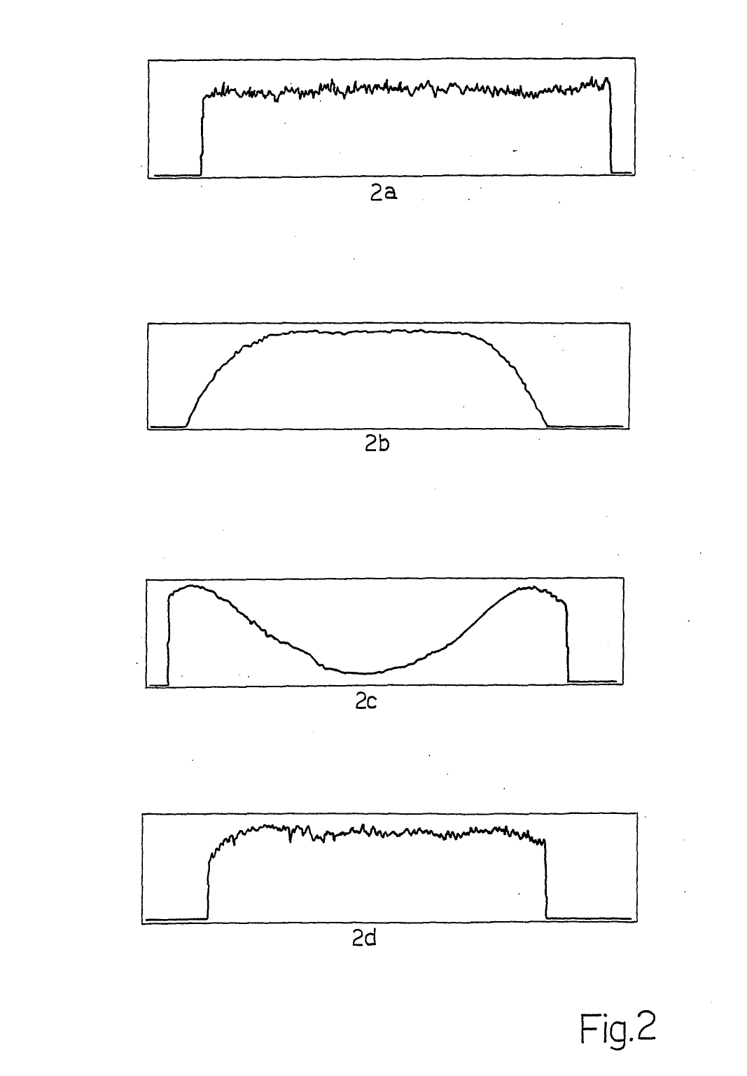

An optical system 1 was produced in BK10 (SCHOTT catalogue) by means of a machining operation guaranteeing a planarity in the order of 15÷20 nm RMS (i.e. approximately 0.1 micron peak-valley) before application of the reflecting treatment (FIG. 1a). FIG. 2a shows the interferometric measurement of the optical surface produced.

On the surface of the optical system 1 as above, a reflecting multilayer 2 of particular interest was deposited which, due to the residual stress, caused convex deformation of the optical system 1 (FIG. 1b). The entity of the deformation induced by the reflecting multilayer 2 was assessed and quantified by interferometric measurements which show a planarity value altered by a factor 5÷10 (1÷2 micron peak-valley, i.e. approximately 80÷120 nm RMS) with respect to the original as shown in FIG. 2b.

The deforming layer was designed on the basis of the data relative to the deformation caused by the reflecting multilayer 2: the material to be used and its thickness was identified by means of experimentation.

Once the above design parameters had been obtained experimentally, a deforming layer 3 was deposited on the optical system 1 (FIG. 1c), generating a deformation equal and opposite to the one, generated by the reflecting multilayer 2 alone, as is highlighted by the values of the interferometric measurements shown in FIG. 2c.

At this point, the reflecting multilayer 2 was deposited on the deforming layer 3, obtaining a mirror 4 (FIG. 1d) on which the interferometer measurements confirmed the initial planarity value in the order of 15÷20 nm RMS, as illustrated in FIG. 2d.

In the example described above, the deforming layer 3 of the controlled pre-deformation treatment consists of titanium dioxide.

Unlike the example, the deforming layer can be produced by a multilayer consisting alternately of two or more materials.

The type of materials to use for the controlled pre-deformation treatment, the thickness of the layers and their total number depend on the type of residual deformation to be annulled. The residual deformation, in turn, depends on the characteristics of the reflecting treatment and the optical system on which it is performed.

As is evident from the above description, the controlled pre-deformation treatment of the method subject of the present invention is completely independent of the subsequent reflecting treatment and does not in any way alter optical performance and resistance. This means that the reflecting treatment can be designed and produced choosing the best structure and best type of materials possible, the sole objective being to maximise the required optical performance and resistance, without any need to worry about possible deformations of the optical system. Thanks to the absence of constraints in terms of choice of materials and structure, it is possible to provide reflecting treatments with very high optical performance, without the minimum risk of deforming the optical system on which they are deposited.

Furthermore, the controlled pre-deformation treatment of the method subject of the present invention does not require machining operations for stiffening the surface to counter the deformation induced by the reflecting treatment, with consequent saving in terms of mass, time and cost. Lastly, the controlled pre-deformation treatment of the method subject of the present invention reduces the components to be discarded, since there is no risk of deforming the optical system during the production phase of the reflecting treatment.

1. A method for the production of a mirror, the mirror comprising an optical system and a reflecting treatment made up of one or more layers of selected materials deposited on a surface of the optical system; said method being characterised in that it comprises a preliminary controlled pre-deformation treatment of said optical system comprising the steps of:
determining the deformation of the optical system caused by the selected reflecting treatment;
designing a deforming layer such as to produce on said optical system a deformation opposite to the determined deformation caused by said selected reflecting treatment; and
depositing said deforming layer on said optical system, on which said selected reflecting treatment will be subsequently deposited.

2. The method for the production of a mirror as claimed in claim 1, characterised in that said deforming layer comprises a layer of titanium dioxide.

3. The method for the production of a mirror as claimed in claim 1, characterised in that said deforming layer comprises a plurality of layers of different materials.

4. A mirror produced by means of deposition of a reflecting layer, characterised in that the mirror is produced by the method according to claim 1.
